(19) United States
(12) Patent Application Publication
(10) Pub. No.: US 2010/0007540 A1
(43) Pub. Date: Jan. 14, 2010

(54) BINARY CONTROLLER AND POWER SUPPLY WITH A BINARY CONTROLLER

(75) Inventors: Peter Lurkens, Aachen (DE); Thomas Scheel, Stolberg (DE); Christian Hattrup, Wurselen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/373,957

(22) PCT Filed: Jul. 10, 2007
(86) PCT No.: PCT/IB07/52733

§ 371 Date: Jan. 15, 2009

(30) Foreign Application Priority Data
Jul. 21, 2006 (EP) 06117640.0

(51) Int. Cl. H03M 1/34; H03M 1/12

(52) U.S. Cl. 341/158; 341/155

(57) ABSTRACT

A controller is described, which is particularly suited for a power supply with switching elements (S1, S2), such as a switching mode power supply. The controller comprises a logical unit (18) which calculates a binary state value Zₖ by a first logical operation from a binary input value I and a prior binary state value Zₖ₋₁. The logical unit further calculates a binary output value Y by a second logical operation from the binary input value I and the binary state value Zₖ. In this way, fast and efficient fully digital control may be realized especially for a switching mode power supply, where the binary input value I is a comparator value and the binary output value Y is used to drive the switch elements (S1, S2). An adaptation unit (20), which may be a signal processor, determines the logical operations and delivers them to the logical unit (18) during operation of the controller unit (16).

The present invention generally relates to automatic control, and more specifically to a controller unit and a method for operating a controller unit as well as a power supply unit including a controller unit.

There are various types of automatic controllers which use closed-loop control methods to control different types of systems. Analog controllers are well-known but suffer from disadvantages such as complicated design and parameter variations.

Digital controllers are known which translate control theory as applied to analog controllers into the digital domain. In such digital controllers, analog input values are converted into digital form by A/D converters. These digital values are processed, e.g. in a signal processor. D/A converters are used for converting the calculated output values into analog parameters used to actually effect control of the system.

In such digital controllers, the digital values represent (quasi-) continuous values. E.g. an 8-bit representation of an input value is a quantisized representation of a continuous parameter which may take any of 255 available values.

While this type of digital controller eliminates problems such as parameter changes, there are control tasks where the required high resolution and/or high frequency necessitate expensive high-speed A/D converters as well as extremely fast digital signal processors (DSP).

One type of controlled systems which for many applications require fast and exact control are power supply circuits. A switching mode power supply may comprise one out of a large number of known converter topologies, where in each case the circuit comprises one or more switching elements, i.e. control elements that alternate between typically no more than two states: on/off. There are applications for this type of power supply circuit, e.g. power supply for a lamp in time sequential projection systems, with high demands with regard to speed (required rapid changes in light intensity) and precision (light fidelity). In these applications, digital control circuits with high resolution, including high speed A/D converters and DSPs implementing cycle-by-cycle control in high frequency converters are driven to their limits with respect to computation speed.

U.S. Pat. No. 5,629,610 describes a “fully digital” current mode PWM controller. Such PWM output stages may be used for different systems, such as DC-DC converters. The control circuit drives a power switch that is commonly constituted by a power transistor, such as a field effect transistor (e.g. MOSFET). In voltage mode, an output voltage is controlled, whereas is current mode a control of the current flowing through the output stage is effected.

The controller includes two comparators establishing different current thresholds. A further comparator provided to compare the output voltage to a preset threshold delivers a further binary signal. The binary signals from the comparators are fed to a multi-input logic circuit, which is implemented as a logic NOR gate. The output of this logic operation is fed to a bistable circuit providing a driving signal for an output switch. A disadvantage, however, is that in between the two threshold limits, no information is produced about the actual value of the current, and thus no control is possible.

The use of binary input signals (in this case: comparator signals) and the use of one or more binary output values (on/off signals for a switching element) makes it possible to use logical operations for the controller function. Such logical operations, in the case of U.S. Pat. No. 5,629,610 a NOR gate, may easily be implemented even at very high frequencies. Such a “fully digital” type of controller avoids both the disadvantages associated with an analog controller as well as those of a digital controller using A/D converters and a signal processor.

It is the object of the present invention to provide a controller unit and an operating method therefor as well as a power supply unit including a controller unit which are well suited for high-speed control while at the same time remaining flexible with regard to different control tasks.

This object is achieved by a controller unit according to claim 1, a power supply unit according to claim 8 and a method for operating a controller according to claim 15. Dependent claims refer to preferred embodiments of the invention.

According to the invention, the controller comprises a logical unit and an adaptation unit. The logical unit works as a purely binary controller, which calculates one or more binary output values by performing logical operations, and can therefore work very fast. The adaptation unit determines the logical operations to be used in the logical unit and delivers them to the logical unit during the operation of the controller, i.e. while the logical unit is actively performing the closed-loop control.

By realizing a controller with this structure, very fast and efficient control may be achieved while overcoming the disadvantages of prior known controllers. Logical unit and adaptation unit may be implemented fully digital, so that problems associated with analog processing (tolerances etc.) are avoided. Also, expensive high-speed A/D converters with high resolution are not required. The computation speed within the logical unit can, due to the simplicity of logical operations performed on binary values, be extremely high, enabling true cycle-by-cycle control in power supply applications. At the same time, controller behavior may efficiently be influenced by the adaptation unit. This unit, which will typically be implemented as a more sophisticated control element, and may comprise a microprocessor or signal processor, is not directly involved in the control task, i.e. it does not directly calculate the output value(s). But by supplying the logical operations to the logical unit, it influences this unit's behavior. Thus, the overall controller behavior can easily be implemented in a very flexible way.

According to the invention, the logical unit uses at least a first and a second logic operation. It should be noted that the values used in the logical unit (at least: state value, input value and output value) may be either single binary values (which will be referred to scalar values), i.e. that can only have one of two possible states, or they can be groups of binary values (here referred to a binary vector values), where each element out of the group can have one of two possible states. However, while the latter as a group of values together describe a specific state, they are not digital number representation in a dual number system. This it to be understood in contrast to digitally represented continues values in prior known digital controllers, e.g. 8-bit binary values. In the present contest, a value referred to as a “binary” value (even if it is a binary vector value) is understood to indicate the presence (or not presence) of certain states (e.g.: A current I is greater than a reference value), but not a binary number representation.

During operation, the logical unit calculates a binary state value (scalar or vector) by a first logical operation (or first set of logical operations) performed on a binary input value (vector or scalar) and a prior binary state value. A second logical operation (or second set of logical operations) is performed on the input value and the state value to calculate a binary output value (again, vector or scalar). Generally, the state value, the input value and/or the output value is of vector form, and the corresponding logical operations may be described by a vector-valued logical function. The logical unit may be implemented as at least one binary state machine implementing a logical transition function.

According to a preferred embodiment of the invention, the controller works at a certain clock frequency, where in each clock cycle a binary input value is received and a binary output value is calculated. However, the logical operations are not delivered from the adaptation unit anew for each clock cycle. Instead, after delivery they are used for a plurality of clock cycles. In a corresponding embodiment, while the logical unit may be clocked very fast, the adaptation unit will only supply changed logical operations at a much slower rate. The adaptation unit can thus be implemented more easily without concern for the very tight time limits associated with the high rate of clock cycles needed for efficient control.

According to a further embodiment, the adaptation unit determines the logical operations based on observation of the binary input value, binary state value and/or binary output value. Thus, the whole controller remains fully digital, and also for the adaptation unit no A/D or D/A conversion is used. Especially preferred is an embodiment, where a timing value is used. The timing value indicates the duration between transitions of at least one of the values from a first state to a second state.

Preferably, the digital input value is generated as one or more comparator signals. Preferably, the comparator signal is generated from a comparison of an actual value of the controlled system with a reference value. While this reference value could be variable, and could correspond to an externally given set value, it is preferred to effect a comparison to a constant reference value. Most preferred is a comparison to zero, which may be most easily implemented.

The logical unit may be implemented as a programmable logical device, such as an FPGA. Other possible implementations include a discrete circuit or a ROM in a closed-loop circuit.

The described controller may be used to effectively control a power supply comprising a converter circuit with at least one switching element. The concept applies to all converter circuits including one or more switching elements. The binary output values in this case represent the switching state of the switching element. The input values may be one or more comparator values delivered from the converter circuit, where an electrical value (preferably current and/or voltage) is compared to an electrical reference value.

Preferably, the converter circle is operated in switching cycles. Within each switching cycles, there may be one or more of the following intervals defined:
A switching interval
A switching interval defines the behavior of at least one switching element. During the whole switching interval, the corresponding switching element is in a first state. Before and after the interval, the switching element is in the second state. Thus, the switching interval may e.g. indicate the interval during which a specific switch is turned on. Also, a switching interval may define the behavior not only of a single switching element, but of a switching arrangement with a plurality of switching elements, e.g. a half bridge or full bridge.
A transition interval
A transition interval may be defined from and/or to a transition occurring during the switching cycle. This transition may correspond to a transition of state value, input value, and/or output value from a first state to a second state. Preferably, the transition of an input value is detected either at the start or end of the interval.
A measuring interval
A measuring interval also may be defined as the interval before or after a transition of the above described type.

For the behavior implemented by the logical operations, it is preferred that the switching interval and/or the transition interval have a fixed duration, whereas the duration of the measuring interval is measured. As will become apparent in the description of the preferred embodiment, the described intervals may already define the time-dependent switching behavior implemented by the logical operations. Additionally, there may be further intervals within the switching cycles.

According to a preferred embodiment, the above described measuring interval is delivered to the adaptation unit. It is preferred, that the adaptation unit uses this measurement interval to calculate an electrical output value of the converter circuit. In a preferred embodiment, this electrical output value (which may be an output voltage, but preferably is an output current) is calculated from the measurement interval and further constant (i.e. not changing within a switching cycle) values relating to one or more of the following group: electrical components of the circuit, electrical input to the circuit, and/or timing values implemented by the logical operations. In this preferred implementation, the electrical output is not measured directly, e.g. by A/D converters. Instead, the electrical output is derived from a timing value measurement. Thus, even though the adaptation unit is not directly electrically connected to the converter circuit, but only connected to the logical unit, it may still monitor the operation of the converter circuit.

There are many different types of suitable logical functions possible to implement the control behavior of the logical unit. In a preferred embodiment, the logical operations implement a behavior where at least in a part of each switching cycle, a register of binary values is operated as a shift register. Such a shift register may efficiently implement the behavior during certain intervals of each cycle, which have a predetermined duration.

According to a preferred embodiment, the operating frequency of the logical unit is higher than the cycle frequency of the converter circuit. Here, the cycle frequency is defined as the number of full switching cycles per time unit. The operating frequency of the logical unit on the other hand corresponds to the clock frequency of this unit, where in each clock cycle an input value is processed and an output value is calculated. If the operating frequency is higher than the cycle frequency, it is possible to implement effective control in each switching cycle. In order to allow complete control within a cycle, the operating frequency will generally be significantly higher, e.g. more than 5 times, preferably more than 10 times higher than the cycle frequency.

The forgoing forms and other forms, features and advantages of the invention will become further apparent from the following detailed description of the presently preferred embodiment read in conjunction with the accompanying drawings. The detailed descriptions and drawings are merely illustrative of the invention rather than limiting.

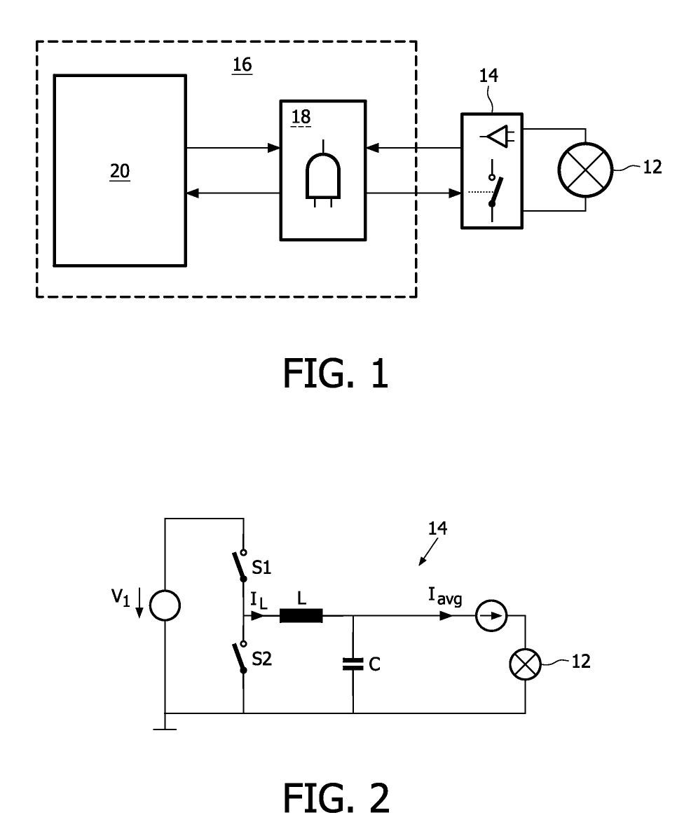

FIG. 1 shows a schematic diagram of a lamp with a power supply and a controller;

FIG. 2 shows a circuit diagram of a switching power supply;

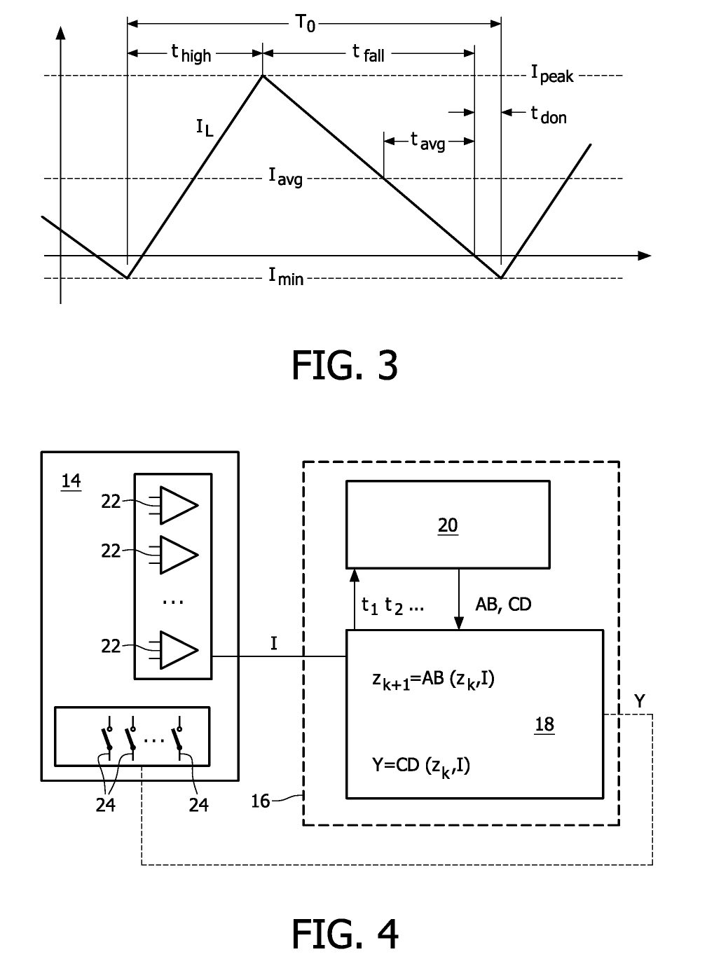

FIG. 3 shows a schematic timing diagram of the current I_{L} in the circuit of FIG. 2;

FIG. 4 shows a schematic diagram of the power supply and controller of FIG. 1 in greater detail;

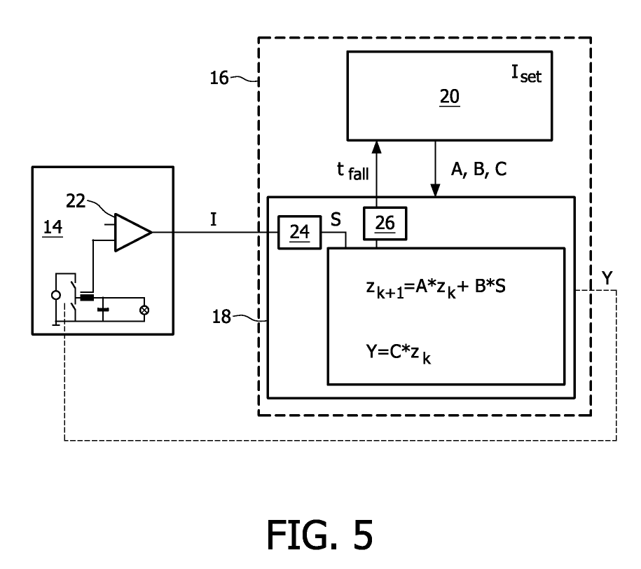

FIG. 5 shows a schematic diagram corresponding to FIG. 4, with the power supply circuit of FIG. 2.

FIG. 1 shows a controlled system 10. A lamp 12 is operated by a switching power supply 14. The power supply 14 is controlled by a controller 16.

The controller 16 comprises a logical unit 18 and an adaptation unit 20.

In the embodiment shown, the lamp 12 is merely an example of a load attached to power supply 14. Instead, any other type of load could be used. However, as will become apparent due to its quick response the effected control is well suited for the demands involved with controlling a lamp e.g. in a time sequential projection system.

The power supply 14 may be any out of a plurality of known switching mode power supplies (SMPS) which may accept and deliver both AC or DC input and output. An SMPS uses one or more switching elements which are continuously switched in a controlled manner between an “on” and an “off” state. There are many different topologies, including, but not necessarily limited to buck, boost, buck-boost, flyback, LLC, LC, LCC, forward, SEPIC etc.

FIG. 4 generally shows an SMPS-circuit 14 controlled by the controller 16. The SMPS 14 delivers an input vector I to the controller 16. The vector I is a vector of a plurality of binary values, each of which corresponds to the output of one of a plurality of comparators 22. The comparators 22 compare electrical values within the SMPS circuit 14 to predefined reference values. For example, an output voltage could be compared to a set voltage, or a current could be compared to a maximum or minimum current value. Also, a current value could be compared to a reference value. Preferably, the reference value could be 0, so that the zero-crossing of the current would be detected. As is easily recognizable for the skilled person, the comparators 22 could be used also for any other types of comparison of electrical values within the SMPS circuit 14.

Further, SMPS circuit 14 comprises a plurality of switching devices 24 which control its behavior. The switches 24 could be arranged in one or more half-bridges, full-bridges etc. according to the topology of the SMPS circuit 14. The state of the switches 24 is governed by an output vector Y delivered from the controller 16 to the SPMS circuit 14. The vector Y is a binary vector generally comprising as many binary elements as there are switches 24 in the circuit 14. (In special cases, e.g. if two switches are always switched in alternating fashion, it is also possible to describe the switches' behavior with only one binary element, so that the dimension of the vector Y may be reduced accordingly.)

Within the logical unit 18 of controller 16, a vector zₖ is stored as vector of binary state values. Again, the individual binary elements of vector zₖ are single binary values which can each have only one of two possible states.

With the three binary vectors, input vector I, output vector Y and state vector zₖ, the behavior of the logical unit 18 may generally be seen as a binary state machine with a logical transition function:

zₖ₊₁=AB(zₖ,I)

Y=CD(zₖ,I)

where AB and CD are generally vector-valued logical functions. These functions may implement any combination of basic logical operations AND, OR, NOT, XOR, etc. This type of functions may be used e.g. for compilers for programmable logic devices (PLD). The functions implemented may be defined in a variety of ways, e.g. by a (logical) circuit diagram, a truth table or in a programming language, e.g. VHDL.

It is now possible to provide logical operations (represented by functions AB, CD) such that the logical unit 18 by itself works as a fully digital controller for SMPS circuit 14.

The functions AB, CD are determined by the adaptation unit 20 in dependence on the particulars of the control task. Within adaptation unit 20, the parameters of the SMPS circuit 14 are known (e.g. values for input voltage, electrical elements etc.). Also, adaptation unit 20 receives details regarding the desired behavior of the system 10, especially the set values for output parameters (in power supply circuits typically output voltage and/or output current) as well as possibly boundary conditions, such as maximum admissible current or voltage values. Based on this knowledge, the adaptation unit 20 determines suitable functions AB, CD.

Within the logical unit 18, the vector zₖ may be seen as the “memory” of the controller. In order to achieve stable control, it will generally be advantageous to not only provide in each clock cycle a memory zₖ₋₁ of only the preceding clock cycle, but also of further past clock cycles. This may be achieved by designing function AB such that zₖ may be effectively used as a shift register, i.e. that a newly calculated zₖ₊₁ contains a prior zₖ in shifted form.

During operation, the adaptation unit 20 monitors the operation of the logical unit 18 in order to influence the behavior of the controller 16, which for each clock cycle of the logical unit 18 is only governed by the above generalized equations. While this monitoring could be achieved in different ways, e.g. by directly measuring electrical values from SPMS circuit 14, and digitize the measured values in A/D converters, preferably the adaptation unit 20 during operation only receives timing values t₁, t₂, etc. from the logical unit 18. These timing values indicate, for one or more of the binary elements of the vectors I, Y and/or zₖ, the duration between transitions from one state to the other. So, for example, a timing value t₁ could indicate the number of clock cycles of the logical unit 18 for which the first binary element of output vector Y has been in state 1 (i.e. how long the first switch 24 of the SPMS 14 has been turned on). In the same way, a timing value t₂ could indicate the time duration for which the second binary element of input vector I has been in state 0. Timing values may easily be delivered by a counter within logical unit 18 triggered by the transition which is incremented in each clock cycle. It should be noted that the above given examples for timing values t₁, t₂ are only examples demonstrating how the operation of logical unit 18 may be monitored, and that different types of timing values may be used for different applications, as will become apparent in connection with the preferred embodiment.

In operation, the adaptation unit 20 continuously determines if the presently set logical operations (represented by functions AB, CD) within logical unit 18 lead to the desired behavior of SMPS 14, so that operation can continue with unchanged functions. In a case where either an external demand for change is recognized (e.g. a new set value for output voltage, output current etc. is given) or an internal need for a change is detected by observation of the timing values t₁, t₂, etc, a new set of functions AB, CD is determined and delivered to the logical unit for immediate execution. After this “update”, logical unit 18 will continue its operation, but from then on with the newly received updated functions AB, CD.

The operation of logical unit 18 may be effected very fast. An SMPS circuit 14 will generally have a switching frequency of more than 1 kHz. In many cases, the frequency will be significantly higher, up to some 100 kHz. In order to still effect use cycle-by-cycle control, i.e. in each switching cycle evaluate at least one, preferably more input vectors I and corresponding output vectors Y, the clock cycle of the logical unit 18 needs to be generally shorter than the switching cycle of the SMPS 14, especially preferred significantly shorter (e.g. at least 10 times shorter, so that the corresponding number of logical operations is executed for each switching cycle). For example, the clock frequency of the logical unit may be above 1 MHz, preferably above 10 MHz.

In an example, the switching frequency is 200 kHz. The clock frequency of the logical unit is 60 MHz, thus 300 times higher. Accordingly, within one switching cycle, there is sufficient resolution on the time axis for exact control.

On the other hand, adaptation unit 20 does not perform cycle-by-cycle control. For each switching cycle, it receives one timing value, or a set of timing values t₁, t₂, etc. As explained above, an update (exchange of functions AB, CD) is only performed if needed, so that no fixed rate for these updates may be given. However, it is clear that the update frequency will be significantly lower than the clock frequency of the logical unit 18, and will generally also be lower than the cycle frequency

$$\frac{1}{{T}_{0}} .$$

Thus, the adaptation unit 20 will have enough time to perform all calculations necessary to determine a set of functions AB, CD as presently needed.

In a preferred embodiment, the logical unit 18 may be implemented as an FPGA. The adaptation unit 20 may be implemented as a signal processor running a program which accepts the timing values t₁, t₂, etc. as input and may generate functions AB, CD as suited for a control demand.

In order to easier understand the role of functions AB, CD within the logical unit 18, these functions may be written in matrix notation as follows:

zₖ₊₁=A*zₖ+B*I

Y=C*zₖ+D*I

where A, B, C, D are matrices of binary values.

It should be noted that the above given equations are purposely written in the same way as the state-space equations known in control theory for continuous (analog or digital) values. However, in the above equations, not only the vector I, Y, zₖ have only binary elements, but also the matrices A, B, C, D describes logical operations.

Within the above notation, the operator “*” describes a logical AND, and the operator “+” describes a logical OR. It should be noted that the above notation is less general then functions AB, CD, because they do not comprise the NOT operation. However, in this notation the functions AB, CD may easily be written and understood for the purposes of the following example.

While in the foregoing, the general concept was described that could be applied to a plurality of converter topologies, in the following, a more specific example will be given.

In the following, the power supply 14 will be assumed to be a buck converter as shown in FIG. 2. In this very simple circuit, an input voltage V₁ is switched by a half bridge of switching elements S1, S2. A series inductance L and a parallel capacitance C are provided. Switches S1 and S2 are switched in alternating fashion. During a time t_{high}, switch S1 is closed while S2 is open, so that a current I_{L} through the inductance L increases. Subsequently, S1 is opened and S2 closed, so that I_{L} decreases. The continuous switching leads to an average current I_{AVG} delivered to the load 12.

FIG. 3 shows a timing diagram of the operation of buck converter 14. The switching occurs in a timing interval T₀. During t_{high}, I_{L} is shown to increase (the shown linear increase here is an approximation of a more realistic, non-linear curve). In the remainder of interval T₀, the current I_{L} drops. After a time t_{fall}, current I_{L} reaches a value I_{ref} (which in this example will be assumed to be zero) and remains below for a following interval t_{don}. Thus, I_{L} alternates between a maximum value Iₚₑₐₖ and a minimum value Iₘᵢₙ.

The reference value I_{ref} is chosen from the interval Iₘᵢₙ<I_{ref}<Iₚₑₐₖ, so that t_{don} is the time interval from the time where the falling I_{L} reaches I_{ref} until the end of the switching period T₀, i.e. until the next switching event occurs. Note that in FIG. 3 I_{ref} is chosen to be zero, which is an easily detectable value.

From the definition of time intervals in FIG. 3, we may define a time interval t_{avg}, which corresponds to the duration between the time when I_{L} is equal to I_{avg}, and the time when I_{L} is equal to I_{ref}:

$${t}_{avg} = \frac{1}{2} ( {t}_{fall} - {t}_{don} ) .$$

For the time t_{fall}, during which S2 is closed and S1 is opened, we can calculate the slope of I_{L} as

$${d \frac{{I}_{L}}{dt} \vert}_{{t}_{fall}} = \frac{- {V}_{lamp}}{L} \\ = \frac{- a \cdot {V}_{1}}{L} \\ = - \frac{{t}_{high}}{{T}_{0}} \frac{{V}_{1}}{L} .$$

where V₁ is the input voltage, L is the inductance, Vₗₐₘₚ is the output voltage and a is the duty cycle.

For a general value of I_{ref}, it follows that the average current I_{avg} may be expressed in dependence on the known values for V₁, L and I_{ref} as well as timing values t_{high}, t_{fall}, t_{don} and T₀:

$${I}_{avg} = - {t}_{avg} \cdot d \frac{{I}_{L}}{dt} + {I}_{ref} = \frac{{t}_{high} \cdot ( {t}_{fall} - {t}_{don} )}{{T}_{0}} \cdot \frac{{V}_{1}}{L} + {I}_{ref} .$$

If I_{ref} is chosen to be zero, as in FIG. 3, the resulting average current I_{avg} may easily be calculated in dependence on known constants V₁, L as well as timing values t_{high}, t_{fall}, t_{don}. For the purposes of control in our example, t_{high} and t_{don} are chosen to be constant values. The only remaining value, t_{fall}, will result in operation as the time between a switching event (end of t_{high}: S₁ is opened, S₂ is closed) and the zero crossing of current I_{L}.

As shown in FIG. 5, the zero crossing of current I_{L} may easily be detected by a comparator 22 which compares I_{L} to zero. In order to be sure, that only the relevant zero crossing (end of t_{fall}: I_{L} changes from positive to negative, see FIG. 3) is detected, we define an auxiliary logical function as follows:

z_{Kk+1}=I

S=z_{Kk}*( [symbol] I)

This function processes the input signal (comparator signal) I and determines an auxiliary signal S which only indicates the relevant zero crossing. This function, which may easily be implemented as a separate digital state machine, is indicated in FIG. 5 as block 24.

The buck converter shown in FIG. 2 should now be controlled by a controller 16 according to FIG. 5. It should be noted that FIG. 5 has the same structure as the general system shown in FIG. 4. However, FIG. 5 shows a specific example, where:
The input vector I and the derived auxiliary input S have a dimension of only 1, i.e. a binary scalar. I is the output of a single comparator 22, which compares the current I_{L} to a value of 0. I is equal to 1 as long as I_{L} is positive. (Thus, in this example, the reference value has been chosen to be I_{ref}=0). Consequently, S is equal to zero at all times, except when the relevant zero crossing occurs.
The output value Y also has a dimension of only 1, i.e. is a binary scalar. Still, Y is used to drive the operation of both switches S1, S2, which are only switched alternatingly. Thus, if Y=1, S1 is on and S2 off, whereas for Y=0, S1 is off and S2 is on.
There is only one timing value t_{fall} delivered from logical unit 18 to adaptation unit 20. This value t_{fall} corresponds to the number of clock cycles starting from the end of t_{high} (where output vector Y switches from 1 to 0) until the current I_{L} becomes negative (i.e. input vector I switches from 1 to 0, indicated by auxiliary signal S becoming 1 for one cycle).

The logical unit 18 now supplies matrices A, B, C, D, which implement the above described control strategy, i.e. which implement a control behavior with fixed t_{high} and t_{don}.

In the following equations, an example of corresponding matrices will be given. It should be noted that for the purposes of this example, a very low resolution (i.e. number of clock cycles of the logical unit 18 per switching cycle of the controlled converter system) has been chosen. Here, the maximum time for both t_{high} and t_{don} is chosen to be 4 clock cycles each. Accordingly, the resulting matrices are of reduced dimension, so that they may easily be shown here. It should be noted however, that while such a reduced resolution may be applicable in some cases, it is generally preferred to use a significantly higher resolution.

The following equation implements control with t_{high}=4 clock cycles and t_{don}=4 clock cycles:

$$( \begin{matrix}{z}_{0 , k + 1} \\ {z}_{1 , k + 1} \\ {z}_{2 , k + 1} \\ {z}_{3 , k + 1} \\ {z}_{4 , k + 1} \\ {z}_{5 , k + 1} \\ {z}_{6 , k + 1} \\ {z}_{7 , k + 1}\end{matrix} ) = ( \begin{matrix}0 & 0 & 0 & 0 & 0 & 0 & 0 & 0 \\ 1 & 0 & 0 & 0 & 0 & 0 & 0 & 0 \\ 0 & 1 & 0 & 0 & 0 & 0 & 0 & 0 \\ 0 & 0 & 1 & 0 & 0 & 0 & 0 & 0 \\ 0 & 0 & 0 & 1 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0\end{matrix} ) * ( \begin{matrix}{z}_{0 , k} \\ {z}_{1 , k} \\ {z}_{2 , k} \\ {z}_{3 , k} \\ {z}_{4 , k} \\ {z}_{5 , k} \\ {z}_{6 , k} \\ {z}_{7 , k}\end{matrix} ) + ( \begin{matrix}1 \\ 0 \\ 0 \\ 0 \\ 0 \\ 0 \\ 0 \\ 0\end{matrix} ) * S$$

$$Y = ( 0 \; 0 \; 0 \; 0 \; 1 \; 1 \; 1 \; 1 ) * ( \begin{matrix}{z}_{0 , k} \\ {z}_{1 , k} \\ {z}_{2 , k} \\ {z}_{3 , k} \\ {z}_{4 , k} \\ {z}_{5 , k} \\ {z}_{6 , k} \\ {z}_{7 , k}\end{matrix} ) .$$

With this setting for matrices A, B, C, the following control behavior is achieved:

Let us assume that vector zₖ is initialized with all elements zero. Correspondingly, the output Y is calculated as 0 (S₁ off, S₂ on).

Now, the signal S is set to 1 for one cycle. In this cycle, the newly calculated vector zₖ has z_{0,k}=1, and all other elements are zero. Output signal Y remains at 0. Because of the way matrix A is designed (all elements 0, except for a secondary diagonal with all values 1) the state machine works in a way that vector zₖ essentially behaves as a shift register. With each clock cycle, the state “1” now propagates through the vector zₖ.

Within the first four cycles, the output signal Y remains at 0. This is due to the design of matrix C, which has only zeros in the first four elements. Thus, the converter remains in the low-state (S₁ open, S₂ closed).

Within the fifth cycle, element z_{4,k} is set to 1. This leads to a change in the output signal Y, which now reaches 1. S₁ is switched on, S₂ is switched off. Accordingly, time period t_{high} begins.

Within the eighth cycle, all elements of zₖ are set to 0 again. Since the last column of matrix A only contains values of 0, the “1”-state of element z_{7,k} does not propagate.

Thus, also output signal Y returns to 0. Within the next cycles, as long as input signal F remains at 0, all elements of zₖ, and thus output signal Y also remain at 0. This corresponds to the time period t_{fall} in FIG. 3.

After time period t_{fall}, current I_{L} reaches zero. Then, S assumes a value of 1 for one cycle, and the above described procedure starts again. Thus, the above shown matrices A, B, C implement a control with t_{high}=4 cycles, t_{don}=4 cycles and a variable t_{fall}.

A different design of these matrices will implement different values for t_{high}, t_{don}. The following example shows identical matrices B, C, but a different matrix A. This matrix A implements a t_{don} of 2 cycles and a t_{high} of 3 cycles:

$$( \begin{matrix}{z}_{0 , k + 1} \\ {z}_{1 , k + 1} \\ {z}_{2 , k + 1} \\ {z}_{3 , k + 1} \\ {z}_{4 , k + 1} \\ {z}_{5 , k + 1} \\ {z}_{6 , k + 1} \\ {z}_{7 , k + 1}\end{matrix} ) = ( \begin{matrix}0 & 0 & 0 & 0 & 0 & 0 & 0 & 0 \\ 1 & 0 & 0 & 0 & 0 & 0 & 0 & 0 \\ 0 & 0 & 0 & 0 & 0 & 0 & 0 & 0 \\ 0 & 0 & 0 & 0 & 0 & 0 & 0 & 0 \\ 0 & 1 & 0 & 0 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 0 & 0\end{matrix} ) * ( \begin{matrix}{z}_{0 , k} \\ {z}_{1 , k} \\ {z}_{2 , k} \\ {z}_{3 , k} \\ {z}_{4 , k} \\ {z}_{5 , k} \\ {z}_{6 , k} \\ {z}_{7 , k}\end{matrix} ) + ( \begin{matrix}1 \\ 0 \\ 0 \\ 0 \\ 0 \\ 0 \\ 0 \\ 0\end{matrix} ) * S$$

$$Y = ( 0 \; 0 \; 0 \; 0 \; 1 \; 1 \; 1 \; 1 ) * ( \begin{matrix}{z}_{0 , k} \\ {z}_{1 , k} \\ {z}_{2 , k} \\ {z}_{3 , k} \\ {z}_{4 , k} \\ {z}_{5 , k} \\ {z}_{6 , k} \\ {z}_{7 , k}\end{matrix} )$$

It has thus been shown, how—while only using a digital state machine—cycle-by-cycle control of the converter circuit may be effected.

As shown above, the resulting average current may easily be calculated from known fixed values (V₁, L, t_{high}, t_{don}) and the resulting, variable value of t_{fall}. Thus, by measuring t_{fall}, the resulting current I_{avg} may be obtained without any additional measurements, such as by A/D converters.

The duration of t_{fall} may be measured by a separate state machine within logical unit 18. This state machine uses a binary state vector z_{M,k} calculated according to the following equation:

$$( \begin{matrix}{z}_{M 0 , k + 1} \\ {z}_{M 1 , k + 1} \\ {z}_{M 2 , k + 1} \\ {z}_{M 3 , k + 1}\end{matrix} ) = ( \begin{matrix}0 & 0 & 0 & 0 \\ 1 & 0 & 0 & 0 \\ 0 & 1 & 0 & 0 \\ 0 & 0 & 1 & 0\end{matrix} ) * ( \begin{matrix}{z}_{M 0 , k} \\ {z}_{M 1 , k} \\ {z}_{M 2 , k} \\ {z}_{M 3 , k}\end{matrix} ) + ( \begin{matrix}0 & 0 & 0 & 0 & 0 & 0 & 0 & 1 \\ 0 & 0 & 0 & 0 & 0 & 0 & 0 & 1 \\ 0 & 0 & 0 & 0 & 0 & 0 & 0 & 1 \\ 0 & 0 & 0 & 0 & 0 & 0 & 0 & 1\end{matrix} ) * z$$

This separate state machine, which in FIG. 5 is indicated as box 26, also implements a shift register. The time measuring state vector z_{M} is initialized with all elements 1 at the start of t_{fall}, i.e. in the cycle where the last element of state vector z, z_{7,k} reaches 1. In each cycle of t_{fall}, z_{M} is shifted one step. At the time where signal S indicates the start of a new cycle (zero crossing of current I_{L}), measuring vector z_{M} represents the duration of t_{fall} by the number of produced “0”-elements, i.e. the number of clock cycles until the zero crossing occured.

Thus, for each switching cycle, the signal processor 20 receives one digital value for the time t_{fall} (It is preferred, that at the time where signal S reaches 1 the value of z_{M} is stored in a register for subsequent reading by signal processor 20). According to the above mentioned equation, signal processor 20 can thus calculate I_{avg}. Signal processor 20 may determine if the resulting I_{avg} is satisfactory, or if it deviates from a set value Iₛₑₜ. In order to reach a desired value of I_{avg}, the signal processor 20 may exchange the matrix A (or C), thus providing different values for t_{high} and t_{don} as described above, until a desired I_{avg} is reached.

The above described embodiment should be understood as exemplary embodiment of the invention only and should be not be construed as limiting. As recognizable for the skilled person, there are a number of alternatives and modifications possible.

While in the above examples the controlled system is an SMPS, the general concept of a fully digital controller based on logical operations that are determined and updated by an adaptation unit could be applied to a plurality of different control tasks.

Such different control tasks will most preferably involve cyclic systems, where the actuating value consist of one or more binary values, e.g. where one or more switches are turned on and off in a cyclic manner. Also, the controlled system should provide one or more binary output signals, e.g. comparator signals.

1. Controller unit comprising
a logical unit (18),
said logical unit (18) being adapted to calculate at least a binary state value (zk) by a first logical operation (AB) performed at least on one or both of a binary input value (I) and a prior binary state value (zk−1),
where said logical unit (18) is further adapted to calculate at least a binary output value (Y) by a second logical operation (CD) performed at least on one or both of said input value (I) and said state value (zk),
and an adaptation unit (20) adapted to determine at least a part of said first and/or said second logical operation and for delivering said part of said operation to said logical unit (18) during operation of said controller unit (16).

2. Unit according to claim 1, where
at least one of said logical operations is implemented by at least one binary state machine implementing a logical transition function (AB, CD),
and said logical unit (18)
calculates a plurality of binary state values (zk),
and/or processes a plurality of binary input values (I),
and/or calculates a plurality of binary output values (Y).

3. Unit according to claim 1, where
said logical unit (18) works according to clock cycles,
where in each clock cycle a binary input value (I) is received,
and where in each said clock cycle a binary output value (Y) is calculated,
where after delivery of said part of said logical operation, said logical unit (18) uses said part of said operation for a plurality of said cycles.

4. Unit according to claim 1, where
said adaptation unit (20) determines said logical operations in dependence on a timing value (t1, t2, tfall) indicating the duration between a transition of at least one of said values from a first state to a second state.

5. Unit according to claim 1, where
said digital input value (I) is generated as one or more comparator (22) signals.

6. Unit according to claim 1, where
said logical unit (18) comprises a programmable logic device.

7. Unit according to claim 1, where
said parameter unit (20) comprises a microprocessor or signal processor unit.

8. Power supply unit comprising
a converter circuit (14) comprising at least one switching element (24, S1, S2),
and at least one comparator (22) for comparing an electrical value in said converter circuit (14) to an electrical reference value and for delivering a binary comparator value (I),
said unit further comprising a controller unit (16) according to claim 1, where said binary input value (I) is said comparator value, and where said binary output value (Y) is used to drive said switching element (24, S1, S2).

9. Unit according to claim 8, where
said converter circuit (14) is operated in switching cycles,
where in each switching cycle there is a switching interval (thigh), during which one of said switching elements (24, S1, S2) is in a first state, where before and after said switching interval (thigh) said switching element (25, S1, S2) is in a second state,
where said logical operations (AB, CD) implement a behavior where said switching interval (thigh) lasts for a fixed duration.

10. Unit according to claim 8, where
said converter circuit (14) is operated in switching cycles,
where in each switching cycle there is a transition of at least one of said state value, said input value or said output value from a first state to a second state,
where in each switching cycle there is a transition interval (tdon), where at the start or at the end of said transition interval (tdon) said transition occurs,
where said logical operations (AB, CD) implement a behavior where said transition interval (tdon) lasts for a fixed duration.

11. Unit according to claim 8, where
said converter circuit (14) is operated in switching cycles,
where in each switching cycle there is a transition of at least one of said state value, said input value or said output value from a first state to a second state,
where in each switching cycle, there is a measuring interval (tfall), where at the start or at the end of said measuring interval (tfall) said transition occurs,
where the duration of said measuring interval (tfall) is measured and delivered to said adaptation unit (20).

12. Unit according to claim 11, where
said adaptation unit (20) calculates an electrical output value (Iavg) of said converter circuit (14) from said measuring interval (tfall) and further constant values (L) relating to electric components of said circuit (14), to the electrical input (V1) to said circuit (14) and to timing values (thigh, tdon) implemented by said logical operations (AB, CD).

13. Unit according to claim 8, where
said converter circuit (14) is operated in switching cycles,
where said logical operations (AB, CD) implement a behavior where at least in a part of each cycle a register of binary values (zk) is operated as a shift register.

14. Unit according to claim 8, where
said converter circuit is operated according to a cycle frequency,
and where said logical unit (18) has a clock frequency determining a duration of clock cycles, where in each clock cycle a binary input value (I) is received and a binary output value (Y) is calculated,
and where said clock frequency is higher than said cycle frequency.

15. Method for operating a controller, where
at least a binary state value (zk) is calculated by a first logical operation performed at least on one or both of a binary input value (I) and a prior binary state value (zk−1),
and where at least a binary output value (Y) is calculated by a second logic operation performed at least on one or both of said input value (I) and said binary state value (zk),
and where during operation of said controller (16), at least a part of said first logical operation and/or said second logical operation is adapted.
